(19) United States
(12) Patent Application Publication
(10) Pub. No.: US 2006/0023552 A1
(43) Pub. Date: Feb. 2, 2006

(54) Read/write methods for limited memory access applications

(75) Inventors: Anthony Gus Aipperspach, Rochester, MN (US); Peichun Peter Liu, Austin, TX (US); Jieming Qi, Austin, TX (US)

Correspondence Address: IBM CORP. (WIP);c/o WALDER INTELLECTUAL PROPERTY LAW, P.C., P.O. BOX 832745, RICHARDSON, TX, 75083, US

(73) Assignee: International Business Machines Corporation, Armonk, NY (US)

(21) Appl. No.: 10/891,770

(22) Filed: Jul. 15, 2004

(51) Int. Cl. G11C 5/14

(52) U.S. Cl. 365/227

(57) ABSTRACT

A method, an apparatus, and a computer program are provided for reducing power consumption and area of a memory subsystem. In many typical memory subsystems, dynamic topologies are employed to detect logic levels in memory; however, dynamic topologies often require clocking. Both power and area are consumed as a result of the clocking. To combat the consumption of power and area, the memory subsystem has been modified so that an enable signal, that must be present, is utilized instead to provide the clocking.

### FIELD OF THE INVENTION

The present invention relates generally to memory devices, and more particularly, to read and write logic of a memory device.

### DESCRIPTION OF THE RELATED ART

In microprocessor systems, memory subsystems are both an integral and important components. Because of the ever-increasing speeds of microprocessors and ever-decreasing sizes, the demand on memory subsystems also increases. The memory subsystems have to have fast access times, to have low power consumption, and to have small areas. In addition, the memories must be reliable. The combination of all of these requirements makes memory design a challenging task.

Typically, there are two common techniques for designing memories: memories with dynamic topologies and memories with sense amplifiers. Sense amplifiers detect logic levels of the given memory cells with small voltage inputs by utilizing two signal inputs. Dynamic topologies, too, sense logic levels of memory cells, but dynamic topologies are single ended, which do not require two input signals like the sense amplifiers. Also, both topologies are usually clocked and require precharging after memory access. However, by utilizing a clocked dynamic topology, the load on the clock is higher, increasing the amount of power required to operate the memory subsystem.

Also, as a result of the increasing speed of the microprocessors, power consumption and power management have become an increasingly important issue. Clocks, for example, are provided by a clocking distribution network, which can include Phased Locked Loops (PLLs). The clocks, though, are an integral component of both the microprocessor system and the memory subsystems, especially those memories with dynamic topologies. Up to 60% of power consumption of a system, can result from the clocks, or usage thereof.

Therefore, there is a need for a method and/or apparatus for reducing the load on a clock in a memory subsystem that at least addresses some of the problems associated with conventional memory subsystems.

### SUMMARY OF THE INVENTION

The present invention provides a method, an apparatus, and a computer program for limiting power for operations in memory device. A memory array and wordline generating circuitry are provided. The wordline generator, however, utilizes a plurality of operation enable signals as a clocking signal.

### BRIEF DESCRIPTION OF THE DRAWINGS

For a more complete understanding of the present invention and the advantages thereof, reference is now made to the following descriptions taken in conjunction with the accompanying drawings, in which:

FIG. 1 is a block diagram depicting a conventional memory device;

FIG. 2 is a block diagram depicting functional operation for wordline outputs for a conventional memory device;

FIG. 3 is a timing diagram depicting the operation of a conventional memory device;

FIG. 4 is a block diagram depicting a modified memory device;

FIG. 5 is a block diagram depicting functional operation for wordline outputs for a modified memory device; and

FIG. 6 is a timing diagram depicting the operation of a modified memory device.

### DETAILED DESCRIPTION

In the following discussion, numerous specific details are set forth to provide a thorough understanding of the present invention. However, those skilled in the art will appreciate that the present invention may be practiced without such specific details. In other instances, well-known elements have been illustrated in schematic or block diagram form in order not to obscure the present invention in unnecessary detail. Additionally, for the most part, details concerning network communications, electro-magnetic signaling techniques, and the like, have been omitted inasmuch as such details are not considered necessary to obtain a complete understanding of the present invention, and are considered to be within the understanding of persons of ordinary skill in the relevant art.

It is further noted that, unless indicated otherwise, all functions described herein may be performed in either hardware or software, or some combination thereof. In a preferred embodiment, however, the functions are performed by a processor such as a computer or an electronic data processor in accordance with code such as computer program code, software, and/or integrated circuits that are coded to perform such functions, unless indicated otherwise.

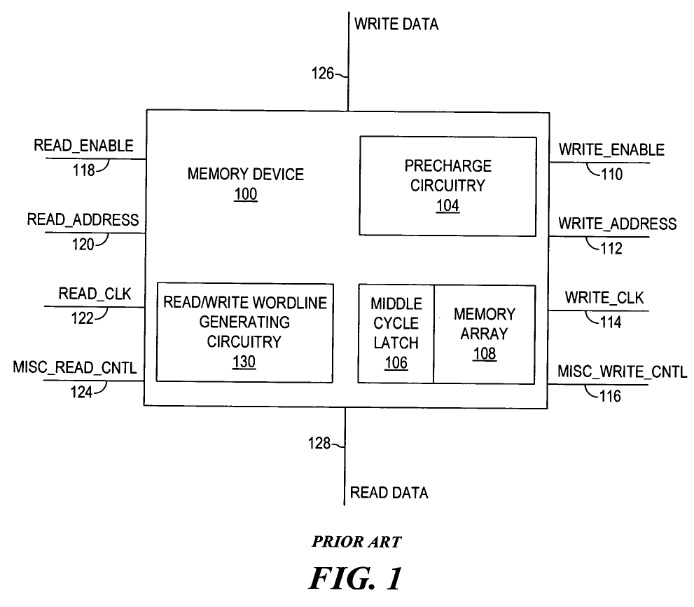

Referring to FIG. 1 of the drawings, the reference numeral 100 generally designates a conventional memory device. The device 100 comprises precharge circuitry 104, a memory array 108 with a middle cycle latch 106, and read/write wordline generating circuitry 130.

The device 100 functions by having multiple signals inputted into the memory device 100. Enablement signals for a read function (READ_ENABLE) are input to the memory device 100 through a first communication channel 118, which is utilized to stop and start a reading process. Addresses for read functions (READ_ADDRESS) are inputted into the memory device 100 through a second communication channel 120. Clocking signals for a read function (READ_CLK) are inputted into the memory device 100 through a third communication channel 122. Miscellaneous read function control signals (MISC_READ_CNTL) are input to the memory device 100 through a fourth communication channel 124. Enablement signals for a write function (WRITE_ENABLE) are input to the memory device 100 through a fifth communication channel 110, which is utilized to stop and start a writing process. Addresses for write functions (WRITE_ADDRESS) are inputted into the memory device 100 through a sixth communication channel 112. Clocking signals for a write function (WRITE_CLK) are inputted into the memory device 100 through a seventh communication channel 114. Miscellaneous write function control signals (MISC_WRITE_CNTL) are input to the memory device 100 through as eighth communication channel 116.

Once the memory device 100 is enable to either read or write to a specified address, then the memory device 100 can receive or transmit the desired data. According to the normal functionality of the memory device 100, a predefined state is utilized. As an example, a predefine state of logic high is utilized. The precharge circuitry 104 provides charge to achieve the predefined state, which is in opposing phase to the enablement signal inputted into the memory device 100 through either the first communication channel 118 or the fifth communication channel 110. That way, if the predefined state is logic high, discharge occurs during enablement of either the read or the write function. Additionally, write data can be inputted to the memory device 100 through a ninth communication channel 126, and read data can be outputted from a tenth communication channel 128.

However, in order to function properly, sufficient time must be allocated to allow for either a read or a write to complete. Processor cores often operate at much higher frequencies than other peripheral devices, such as Direct Memory Access (DMA) devices. For example, a typical processor core frequency is 2 GHz, whereas a typical DMA frequency is 1 GHz. It is not uncommon to have frequency ratios for 2:1 or 3:1. Therefore, the rapid toggling at the processing core frequency may be insufficient to allow for a complete read or write. Hence, the middle cycle latch 106 is utilized to store data at the half cycle of the clocking signal to prevent data loss. The middle cycle latch 106, though, does have a large area and consumes power.

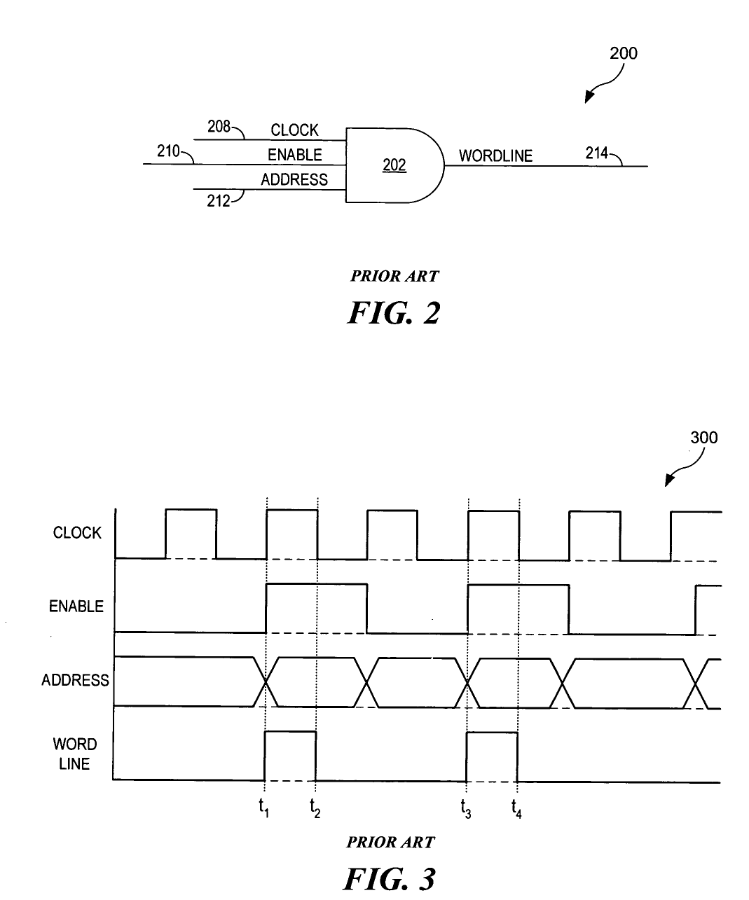

Specifically, the generation of the wordlines is corresponds to inputted data. Referring to FIG. 2 of the drawings, the reference numeral 200 generally designates a block diagram depicting functional operation for wordline outputs for a conventional memory device. The operation comprises an AND gate 202.

The AND gate 202, though, functions by receiving certain input signals. A clocking signal is inputted into the AND gate 202 through a first communication channel 208. An enable signal, such as the READ_ENABLE or WRITE_ENABLE signal, is inputted into the AND gate 202 through a second communication channel 210. Also, an address signal, such as the READ_ADDRESS or WRITE_ADDRESS signal, is inputted into the AND gate 202 through a third communication channel 212. Hence, when all of the respective lines of the AND gate 202 are logic high, then a wordline output signal is transmitted through fourth communication channel 214.

An example Of functionality of the AND gate 202 that utilizes an input clock can be shown with the use of a timing diagram. Referring to FIG. 3 of the drawings, the reference numeral 300 generally designates a timing diagram depicting the operation of the AND gate 202. A clocking signal is shown along with an enable signal. The address data also is shown, where the data input correspond to the rising and falling edges of the enable signal.

The first transition of the word line to logic high first occurs at a first time t₁. At the first time t₁, it is apparent that both the enable signal and the clock are logic high. Clearly, the clocking signal is important to the operation of the logic 200. Additionally, the wordline transitions to logic low at a second time t₂, to logic high at a third time t₃, and to logic low at a fourth time t₄. In each of the transitions, the wordline only becomes logic high when both the clock and the enable signal are at logic high.

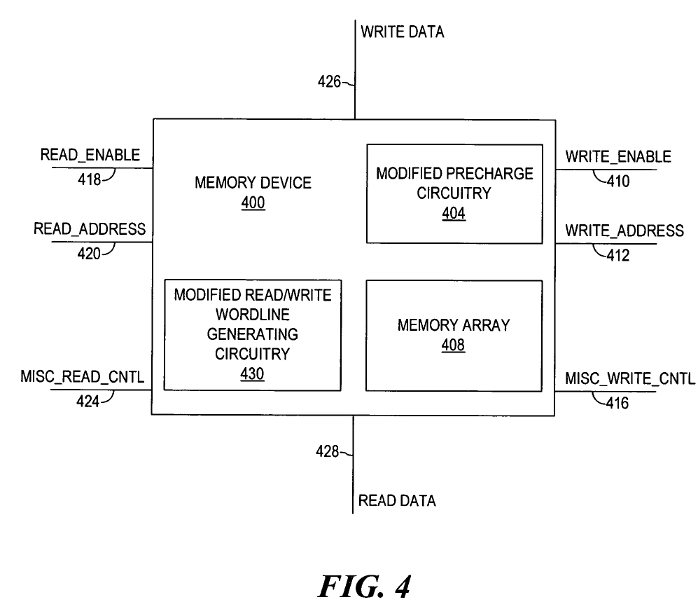

The device 100, though, consumes too much power. Power is required to operate the clock and the clocking system. The requirements for the clock can be significant. Additionally, the middle cycle latch 106 consumes power and occupies area. To alleviate the area and power acquired by the device, modifications can be made. Referring to FIG. 4 of the drawings, the reference numeral 400 generally designated a modified memory device. The memory device 400 comprises modified precharge circuitry 404, modified read/write wordline generating circuitry 430, and a memory array 408.

The device 400 functions by having multiple input signals. READ_ENABLE signals are input to the memory device 400 through a first communication channel 418, which is utilized to stop and start a reading process. READ_ADDRESS signals are inputted into the memory device 400 through a second communication channel 420. MISC_READ_CNTL signals are input to the memory device 400 through a third communication channel 424. WRITE_ENABLE signals are input to the memory device 400 through a fourth communication channel 410, which is utilized to stop and start a writing process. WRITE_ADDRESS signals are inputted into the memory device 400 through a fifth communication channel 412. MISC_WRITE_CNTL signals are input to the memory device 400 through a sixth communication channel 416. The memory device 400, however, does not have any inputted clocking signals for either read or write functions. The enable signals are utilized for clocking instead.

Once the memory device 400 is enabled to either read or write to a specified address, then the memory device 400 can receive or transmit the desired data. According to the normal functionality of the memory device 400, a predefined state is utilized. As an example, a predefine state of logic high is utilized. The precharge circuitry 404 provides charge; however, the precharge circuitry 404 is modified so that there is no need for an inputted clocking signal for either the read function or the write function. The precharge circuitry 404 provides charge in opposing phase to the enablement signal inputted into the memory device 400 through either the first communication channel 418 or the fourth communication channel 410. That way, if the predefined state is logic high, discharge occurs during enablement of either the read or the write function. Additionally, write data can be inputted to the memory device 400 through a tenth communication channel 426, and read data can be outputted from an eleventh communication channel 428.

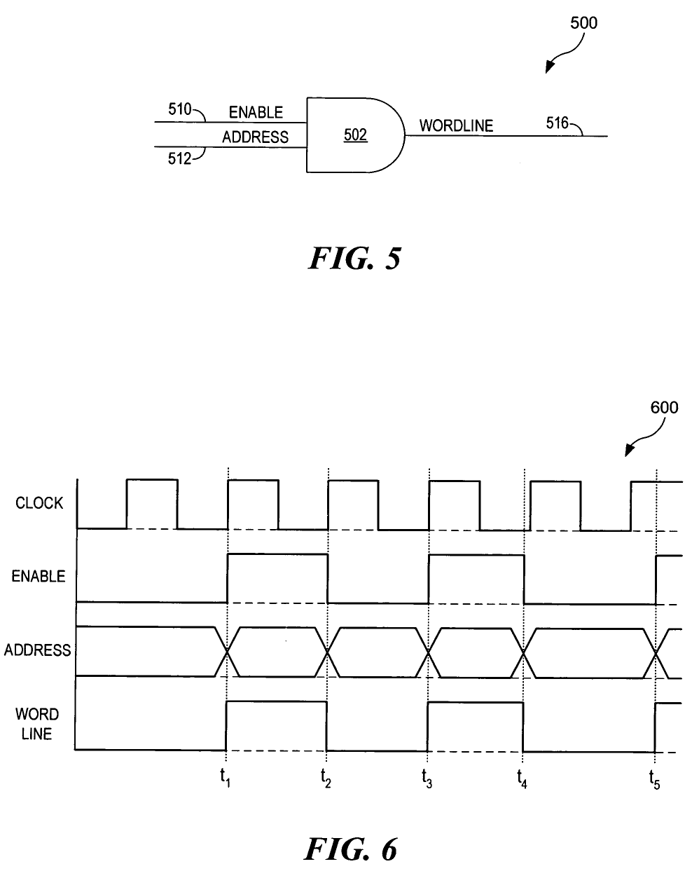

The device 400, though, utilizes a modified read/write wordline generating circuitry 430. Referring to FIG. 5 of the drawings, the reference numeral 500 generally designates functional operation for wordline outputs for a modified memory device. The operation comprises an AND gate 502.

The AND gate 502, however, functions to reduce the load on input clocks to the memory device 400 of FIG. 4. The AND gate 502 receives two input signals. An enable signal, such as the READ_ENABLE or WRITE_ENABLE signal, is inputted into the AND gate 502 through a first communication channel 510. An address signal, such as the READ_ADDRESS or WRITE_ADDRESS signal, is inputted into the AND gate 502 through a second communication channel 512. Hence, when all of the respective lines of the AND gate 502 are logic high, then a wordline output signal is transmitted through the third communication channel 516.

An example of the function of the modified read/write wordline generating circuitry 430 for a word line output that does not utilize an input clock can be show with the use of a timing diagram. Referring to FIG. 6 of the drawings, the reference numeral 600 generally designates a timing diagram depicting the operation of the load reducing logic that does not engage the clock. A clocking signal is shown along with an enable signal. The address data also is shown, where the data input correspond to the rising and falling edges of the enable signal.

The first transition of the word line to logic high first occurs at a first time t₁. Even through the rising edge of the enable signals appears to be synchronized with the clocking signal, the clocking signal is not important to the operation logic 500. Therefore, the word line transitions to logic low at a second time t₂, to logic high at a third time t₃, to logic low at a fourth time t₄, and to logic high at a fifth time t₅. In fact, the word lines transition between logic high and logic low is in coincidence with the enable signal.

By using the operation logic 500, certain advantages can be exploited. A latch, such as the middle cycle latch 106 and its clock load in FIG. 1, can be eliminated. The elimination is advantageous because a latch can utilize many transistors and other component, which can occupy a substantial amount of silicon and consume a substantial amount of power. In addition, the power consumed by the logic gates within the operation logic 500, therefore, is less than that of the operation logic 200 of FIG. 2.

It is understood that the present invention can take many forms and embodiments. Accordingly, several variations may be made in the foregoing without departing from the spirit or the scope of the invention. The capabilities outlined herein allow for the possibility of a variety of programming models. This disclosure should not be read as preferring any particular programming model, but is instead directed to the underlying mechanisms on which these programming models can be built.

Having thus described the present invention by reference to certain of its preferred embodiments, it is noted that the embodiments disclosed are illustrative rather than limiting in nature and that a wide range of variations, modifications, changes, and substitutions are contemplated in the foregoing disclosure and, in some instances, some features of the present invention may be employed without a corresponding use of the other features. Many such variations and modifications may be considered desirable by those skilled in the art based upon a review of the foregoing description of preferred embodiments. Accordingly, it is appropriate that the appended claims be construed broadly and in a manner consistent with the scope of the invention.

1. A method for limiting power for operations in memory device, comprising:
receiving a plurality of operation enable signals by the memory device;
receiving address information by the memory device; and
generating wordlines for a memory array, wherein the step of generating at least employs the plurality of operation enable signals as clocking signals, and wherein the memory device does not receive a separate clock signal as an input.

2. The method of claim 1, wherein the method further comprises:
precharging to a predetermined logic level; and
providing charge at the predetermined logic level to the memory array in opposite phase to the plurality of operation enable signals.

3. The method of claim 1, wherein the step of receiving a plurality of operation enable signals further comprises receiving a plurality of read enable signals.

4. The method of claim 3, wherein the method further comprises reading data from the memory device.

5. The method of claim 1, wherein the step of receiving a plurality of operation enable signals further comprises receiving a plurality of write enable signals.

6. The method of claim 5, wherein the method further comprises writing data to the memory device.

7. An apparatus for limiting power for operations in memory device, comprising:
a memory array; and
wordline generating circuitry for communicated with the memory array that is at least configured to employ a plurality of operation enable signals as a clocking signal, wherein the memory device does not receive a separate clock signal as an input.

8. The apparatus of claim 7, wherein the apparatus further comprises precharge circuitry that is at least configured to precharge to a predetermined logic level in opposite phase to the plurality of operational enable signals.

9. The method of claim 7, wherein the plurality of operation enable signals further comprises a plurality of read enable signals.

10. The method of claim 7, wherein the plurality of operation enable signals further comprises a plurality of write enable signals.

11-16. (canceled)

17. A memory device, comprising:
a plurality of first input channels for receiving operation enable signals in the memory device;
a second input channels for receiving address information in the memory device; and
a wordline generating circuit for generating wordlines for a memory array of the memory device, wherein the generating wordlines at least employs the plurality of operation enable signals as clocking signals, and wherein the memory device does not receive a separate clock signal as an input.

18. The memory device of claim 17, further comprising:
a precharge circuit for precharging to a predetermined logic level and
for providing charge at the predetermined logic level to the memory array in opposite phase to the plurality of operation enable signals.

19. The memory device of claim 17, wherein the plurality of operation enable signals further comprises a plurality of read enable signals.

20. The memory device of claim 19, further comprising a read data output channel for reading data from the memory device.

21. The memory device of claim 17, wherein the plurality of operation enable signals further comprises a plurality of write enable signals.

22. The memory device of claim 21, further comprising a write data input channel for writing data to the memory device.
